(19) United States
(12) Patent Application Publication
(10) Pub. No.: US 2026/0136764 A1
(43) Pub. Date: May 14, 2026

(54) METHOD OF MANUFACTURING DISPLAY DEVICE

(71) Applicant: Magnolia White Corporation, Tokyo (JP)

(72) Inventor: Kenji HARADA, Tokyo (JP)

(73) Assignee: Magnolia White Corporation, Tokyo (JP)

(21) Appl. No.: 19/373,815

(22) Filed: Oct. 30, 2025

(30) Foreign Application Priority Data
Nov. 8, 2024 (JP) 2024-195791

(51) Int. Cl. H10K 59/12; H10K 59/122

(52) U.S. Cl. CPC H10K 59/1201; H10K 59/122

(57) ABSTRACT

According to one embodiment, a manufacturing method of a display device includes steps of forming a lower electrode in a display area for displaying images, forming a rib layer of an inorganic material covering the lower electrode, forming a partition having a lower portion provided on the rib layer and having conductivity and an upper portion provided on the lower portion and protruding relative to a side surface of the lower portion, forming a pixel aperture overlapping the lower electrode in the rib layer, forming an organic layer covering the lower electrode through the pixel aperture, and applying a current between the partition and the lower electrode to electrically insulate the lower portion and the organic layer from each other.

### CROSS-REFERENCE TO RELATED APPLICATIONS

This application is based upon and claims the benefit of priority from Japanese Patent Application No. 2024-195791, filed Nov. 8, 2024, the entire contents of which are incorporated herein by reference.

### FIELD

Embodiments described herein relate generally to a method of manufacturing a display device.

### BACKGROUND

Recently, display devices with organic light-emitting diodes (OLED) applied thereto as display elements have been put into practical use. This type of display devices demand a technique for suppressing degradation in display quality.

### BRIEF DESCRIPTION OF THE DRAWINGS

FIG. 1 is a view showing a configuration example of a display device according to an embodiment.

FIG. 2 is a circuit diagram showing a configuration example applicable to a pixel circuit provided in each subpixel.

FIG. 3 is a schematic plan view showing an example of the layout of subpixels.

FIG. 4 is a schematic cross-sectional view of the display device along the IV-IV line of FIG. 3.

FIG. 5 is a view showing an example of a layer structure applicable to display elements.

FIG. 6 is a schematic cross-sectional view showing an example of a partition and its surrounding.

FIG. 7 is a schematic plan view of a mother substrate according to an embodiment.

FIG. 8 is a schematic plan view of a part of the mother substrate.

FIG. 9A is a schematic cross-sectional view showing a manufacturing process of the display device of the present embodiment.

FIG. 9B is a schematic cross-sectional view showing a process following the process shown in FIG. 9A.

FIG. 9C is a schematic cross-sectional view showing a process following the process shown in FIG. 9B.

FIG. 9D is a schematic cross-sectional view showing a process following the process shown in FIG. 9C.

FIG. 9E is a schematic cross-sectional view showing a process following the process shown in FIG. 9D.

FIG. 9F is a schematic cross-sectional view showing a process following the process shown in FIG. 9E.

FIG. 9G is a schematic cross-sectional view showing a process following the process shown in FIG. 9F.

FIG. 9H is a schematic cross-sectional view showing a process following the process shown in FIG. 9G.

FIG. 9I is a schematic cross-sectional view showing a process following the process shown in FIG. 9H.

FIG. 10A is a schematic cross-sectional view showing an example of a process for electrically insulating an organic layer and a partition from each other.

FIG. 10B is a schematic cross-sectional view showing a process following the process shown in FIG. 10A.

FIG. 10C is a schematic cross-sectional view showing a process following the process shown in FIG. 10B.

FIG. 11 is a circuit diagram in the process shown in FIG. 10A.

FIG. 12A is a schematic cross-sectional view showing another example of the process for electrically insulating the organic layer and the partition from each other.

FIG. 12B is a schematic cross-sectional view showing a process following the process shown in FIG. 12A.

FIG. 13A is a schematic cross-sectional view showing still another example of the process for electrically insulating the organic layer and the partition from each other.

FIG. 13B is a schematic cross-sectional view showing a process following the process shown in FIG. 13A.

FIG. 13C is a schematic cross-sectional view showing a process following the process shown in FIG. 13B.

FIG. 14 is a schematic cross-sectional view showing another example of the process shown in FIG. 13A.

FIG. 15 is a schematic cross-sectional view showing still another example of the process shown in FIG. 13A.

### DETAILED DESCRIPTION

In general, according to one embodiment, a manufacturing method of a display device includes steps of forming a lower electrode in a display area for displaying images, forming a rib layer of an inorganic material covering the lower electrode, forming a partition having a lower portion provided on the rib layer and having conductivity and an upper portion provided on the lower portion and protruding relative to a side surface of the lower portion, forming a pixel aperture overlapping the lower electrode in the rib layer, forming an organic layer covering the lower electrode through the pixel aperture, and applying a current between the partition and the lower electrode to electrically insulate the lower portion and the organic layer from each other.

Embodiments can provide a manufacturing method of a display device capable of suppressing degradation in display quality.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X direction. A direction parallel to the Y-axis is referred to as a Y direction. A direction parallel to the Z-axis is referred to as a Z direction. When various elements are viewed parallel to the Z direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

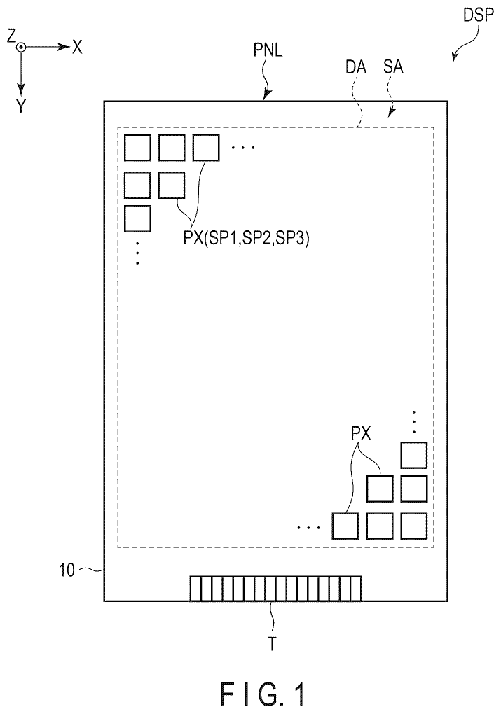

FIG. 1 is a view showing a configuration example of a display device DSP according to an embodiment. The display device DSP comprises a display panel PNL including an insulating substrate 10. The display panel PNL has a display area DA for displaying images and a surrounding area SA around the display area DA. The substrate 10 may be glass or a resinous film having flexibility.

In the present embodiment, the substrate 10 has a rectangular shape extending in the Y direction in plan view. The shape of the substrate 10 in plan view is not limited to a rectangle and may be another shape such as a square, a circle, and an oval.

The display area DA comprises a plurality of pixels PX arranged in a matrix in the X direction and the Y direction. Each pixel PX includes a plurality of subpixels SP displaying different colors. The present embodiment assumes a case where each pixel PX includes three subpixels SP1, SP2, and SP3. For example, the subpixel SP1 displays green, the subpixel SP2 displays blue, and the subpixel SP3 displays red. The colors displayed by the subpixels SP1, SP2, and SP3 are not limited to this example. Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit board applying voltage and signals for driving the display device DSP is connected to the terminal portion T.

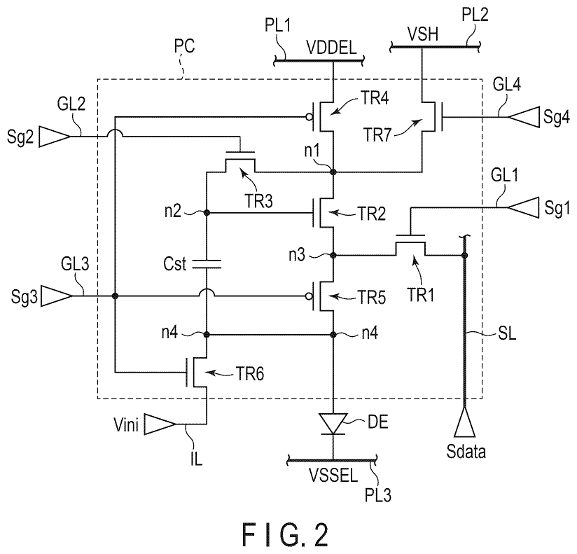

FIG. 2 is a circuit diagram showing a configuration example applicable to a pixel circuit PC, which each of the subpixels SP (SP1, SP2, and SP3) comprises. The pixel circuit PC shown in the figure includes seven transistors TR1 to TR7 and a storage capacitor Cst.

In the following explanation, one of the source and drain electrodes of each of the transistors TR1 to TR7 is referred to as the first electrode, and the other is referred to as the second electrode. Similarly, one electrode of the storage capacitor Cst is referred to as the first electrode, and the other electrode is referred to as the second electrode.

The first electrode of the transistor TR1 is connected to a node n3. The second electrode of the transistor TR1 is connected to a signal line SL supplying video signals Sdata. The video signals Sdata are signals written to pixels for image display.

The transistor TR2 corresponds to a drive transistor applying current to a display element DE included in the subpixel SP. The first electrode of the transistor TR2 is connected to a node n1. The second electrode of the transistor TR2 is connected to the node n3.

The first electrode of the transistor TR3 is connected to the node n1. The second electrode of the transistor TR3 is connected to a node n2.

The first electrode of the transistor TR4 is connected to the node n1. The second electrode of the transistor TR4 is connected to a power line PL1 applying a power source voltage VDDEL.

The first electrode of the transistor TR5 is connected to the node n3. The second electrode of the transistor TR5 is connected to a node n4.

The first electrode of the transistor TR6 is connected to the node n4. The second electrode of the transistor TR6 is connected to an initialization line IL applying an initialization voltage Vini.

The first electrode of the transistor TR7 is connected to the node n1. The second electrode of the transistor TR7 is connected to a power line PL2 supplying a power source voltage VSH.

The first electrode of the storage capacitor Cst is connected to the node n2. The second electrode of the storage capacitor Cst is connected to the node n4.

The gate electrode of the transistor TR1 is connected to a scanning line GL1 supplying scanning signals Sg1. The gate electrode of the transistor TR3 is connected to a scanning line GL2 supplying scanning signals Sg2. The gate electrodes of the transistors TR4, TR5, and TR6 are connected to a scanning line GL3 supplying scanning signals Sg3. The gate electrode of the transistor TR7 is connected to a scanning line GL4 supplying scanning signals Sg4.

The anode of the display element DE is connected to the node n4. The cathode of the display element DE is connected to a power line PL3 applying a power source voltage VSSEL. The power source voltage VDDEL corresponds to an anode voltage applied to the display element DE. The power source voltage VSSEL corresponds to a cathode voltage applied to the display element DE.

The configuration of the pixel circuit PC is not limited to the example shown in FIG. 2. For example, the pixel circuit PC may comprise six or less or eight or more transistors. Further, the pixel circuit PC may comprise a plurality of storage capacitors Cst.

In the circuit configuration shown in FIG. 2, when a low (L) level signal is supplied to the gate electrode of each of the transistors TR1 to TR3, TR6, and TR7, each of the transistors TR1 to TR3, TR6, and TR7 enters the OFF state (a non-conductive state). In contrast, when a high (H) level signal is supplied to the gate electrode of each of the transistors TR1 to TR3, TR6, and TR7, each of the transistors TR1 to TR3, TR6, and TR7 enters the ON state (a conductive state).

Further, when the L-level signal is supplied to the gate electrode of each of the transistors TR4 and TR5, each of the transistors TR4 and TR5 enters the ON state (the conductive state). In contrast, when the H-level signal is supplied to the gate electrode of each of the transistors TR4 and TR5, each of the transistors TR4 and TR5 enters the OFF state (the non-conductive state).

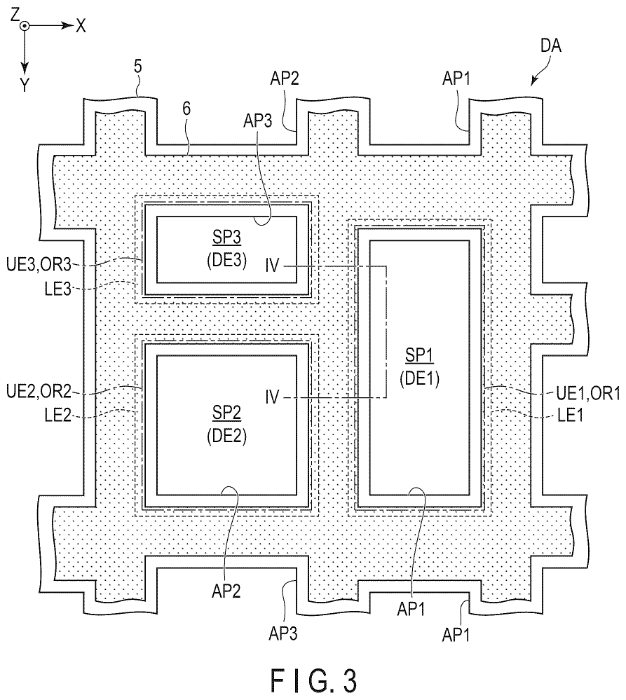

FIG. 3 is a schematic plan view showing an example of the layout of the subpixels SP1, SP2, and SP3. In the example of FIG. 3, the subpixels SP2 and SP3 are arranged with the subpixel SP1 in the X direction. Further, the subpixels SP2 and SP3 are arranged in the Y direction.

When the subpixels SP1, SP2, and SP3 are arranged in this layout, in the display area DA, a column in which the subpixels SP2 and SP3 are alternately arranged in the Y direction and a column in which the plurality of subpixels SP1 are repeatedly arranged in the Y direction are formed. These columns are alternately arranged in the X direction. The layout of the subpixels SP1, SP2, and SP3 is not limited to the example of FIG. 3.

A rib layer 5 is provided in the display area DA. The rib layer 5 has pixel apertures AP1, AP2, and AP3 in the respective subpixels SP1, SP2, and SP3. In the example of FIG. 3, the pixel aperture AP1 is greater than the pixel aperture AP2, and the pixel aperture AP2 is greater than the pixel aperture AP3. Thus, among the subpixels SP1, SP2, and SP3, the aperture ratio of the subpixel SP1 is the greatest, and the aperture ratio of the subpixel SP3 is the least. The size and the shape of each of the pixel apertures AP1, AP2, and AP3 are not limited to the illustrated example.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

Parts overlapping the pixel aperture AP1 of the lower electrode LE1, the upper electrode UE1, and the organic layer OR1 constitute a display element DE1 of the subpixel SP1. Parts overlapping the pixel aperture AP2 of the lower electrode LE2, the upper electrode UE2, and the organic layer OR2 constitute a display element DE2 of the subpixel SP2. Parts overlapping the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

A conductive partition 6 is provided in the display area DA. The partition 6 is located above the rib layer 5 to entirely overlap the rib layer 5. In the example of FIG. 3, the partition 6 has a planar shape similar to that of the rib layer 5. That is, the partition 6 includes an aperture in each of the subpixels SP1, SP2, and SP3. From another viewpoint, each of the rib layer 5 and the partition 6 has a grating shape in plan view and surrounds each of the display elements DE1, DE2, and DE3. The partition 6 functions as lines applying common voltage to the upper electrodes UE1, UE2, and UE3.

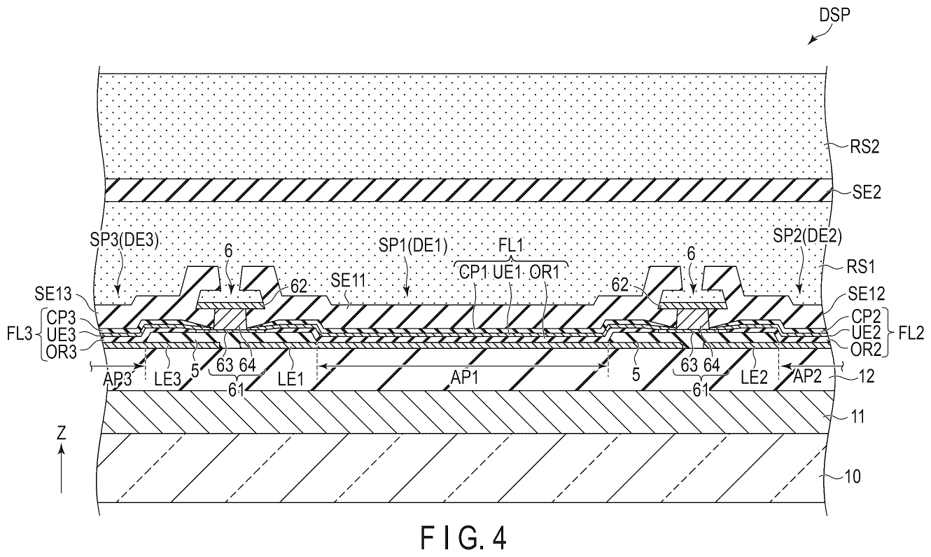

FIG. 4 is a schematic cross-sectional view of the display device DSP along the IV-IV line of FIG. 3. A circuit layer 11 is provided on the substrate 10 described above. The circuit layer 11 includes various circuits and lines such as the pixel circuit PC, the scanning lines GL1 to GL4, the signal lines SL, the power lines PL1 to PL3, and the initialization line IL shown in FIG. 2. The circuit layer 11 is covered with an organic insulating layer 12. The organic insulating layer 12 functions as a planarization film planarizing irregularities formed by the circuit layer 11.

The lower electrodes LE1, LE2, and LE3 are provided on the organic insulating layer 12 and are spaced apart from each other. The rib layer 5 is provided on the organic insulating layer 12 and the lower electrodes LE1, LE2, and LE3. End portions of the lower electrodes LE1, LE2, and LE3 are covered with the rib layer 5. Although not shown in the section of FIG. 4, the lower electrodes LE1, LE2, and LE3 are connected to the respective pixel circuits PC of the circuit layer 11 through respective contact holes provided in the organic insulating layer 12.

The partition 6 includes a conductive lower portion 61 provided on the rib layer 5 and an upper portion 62 provided on the lower portion 61. The upper portion 62 has a width greater than that of the lower portion 61. This configuration causes both end portions of the upper portion 62 to protrude relative to the side surfaces of the lower portion 61. This shape of the partition 6 is called an overhang shape.

In the example of FIG. 4, the lower portion 61 has a bottom layer 63 provided on the rib layer 5 and a stem layer 64 provided on the bottom layer 63. For example, the bottom layer 63 is formed to be thinner than the stem layer 64. In the example of FIG. 4, both end portions of the bottom layer 63 protrude relative to the side surfaces of the stem layer 64. Further, the both end portions of the bottom layer 63 are located between the end portion of the upper portion 62 and the side surface of the stem layer 64 in plan view. The upper portion 62 is provided on the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the side surface of the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of the light emitted from the respective organic layers OR1, OR2, and OR3.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Sealing layers SE11, SE12, and SE13, which cover the respective stacked films FL1, FL2, and FL3 are provided in the respective subpixels SP1, SP2, and SP3. The sealing layer SE11 continuously covers the display element DE1 and the partition 6 around the display element DE1. The sealing layer SE12 continuously covers the display element DE2 and the partition 6 around the display element DE2. The sealing layer SE13 continuously covers the display element DE3 and the partition 6 around the display element DE3.

In the example of FIG. 4, the sealing layer SE11 located on the partition 6 between the subpixels SP1 and SP2 is spaced apart from the sealing layer SE12 located on this partition 6. The sealing layer SE11 located on the partition 6 between the subpixels SP1 and SP3 is spaced apart from the sealing layer SE13 located on this partition 6. Two of the sealing layers SE11, SE12, and SE13 may contact each other above the partition 6.

For example, gaps are formed between the respective sealing layers SE11, SE12, and SE13 and the upper portion 62 of the partition 6. The stacked films FL1, FL2, and FL3 may be provided in at least part of these gaps.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well. FIG. 4 omits the illustration of elements located above the resin layer RS2.

The organic insulating layer 12 is formed of an organic insulating material such as a polyimide. Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). In one example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (organic insulating materials) such as an epoxy resin or an acrylic resin.

Each of the lower electrodes LE1, LE2, and LE3 has a reflective layer and a pair of conductive oxide layers covering the upper and lower surfaces of the reflective layer. The reflective layer is formed of, for example, a metallic material having excellent light-reflecting properties, such as silver. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the cap layers CP1, CP2, and CP3 comprises, for example, a multilayer structure in which a plurality of transparent layers are stacked. These transparent layers may include a layer formed of an inorganic material and a layer formed of an organic material. The transparent layers have refractive indices different from each other. For example, the refractive indices of these transparent layers are different from the refractive indices of the upper electrodes UE1, UE2, and UE3 and the refractive indices of the sealing layers SE11, SE12, and SE13. At least one of the cap layers CP1, CP2, and CP3 may be omitted.

For example, each of the bottom layer 64 and the stem layer 6 of the partition 63 is formed of a metal material. For the metal material of the bottom layer 63, for example, molybdenum (Mo), titanium (Ti), titanium nitride (TiN), a molybdenum-tungsten alloy (MoW), or a molybdenum-niobium alloy (MoNb) can be used. For the metal material of the stem layer 64, for example, aluminum (Al), an aluminum-neodymium alloy (AlNd), an aluminum-yttrium alloy (AlY), or an aluminum-silicon alloy (AlSi) can be used. For example, at least one of the bottom layer 63 and the stem layer 64 may comprise a stacked layer structure in which a plurality of layers are stacked. The stem layer 64 may include a layer formed of an insulating material.

For example, the upper portion 62 of the partition 6 includes a stacked layer structure comprising a lower layer formed of a metal material and an upper layer formed of a conductive oxide. For the metal material forming the lower layer, for example, titanium, a titanium nitride, molybdenum, tungsten, a molybdenum-tungsten alloy, or a molybdenum-niobium alloy may be used. For a conductive oxide forming the top layer, for example, ITO or IZO may be used. The upper portion 62 may comprise a single-layer structure of a metal material. The upper portion 62 may further include a layer formed of an insulating material.

The partition 6 is supplied with common voltage. This common voltage is applied to each of the upper electrodes UE1, UE2, and UE3 in contact with the side surfaces of the lower portions 61. Pixel voltages according to the video signals of the signal lines SL are applied to the lower electrodes LE1, LE2, and LE3 through the respective pixel circuits PC provided in the subpixels SP1, SP2, and SP3.

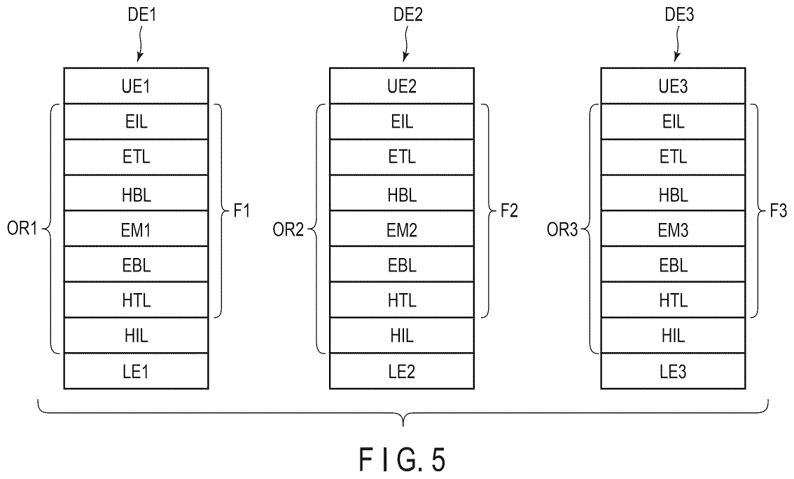

In one example, the organic layers OR1, OR2, and OR3 are configured to emit colors different from each other. In another example, the light emitting layers of the organic layers OR1, OR2, and OR3 may emit light of the same color (for example, white). In this case, the display device DSP may comprise a color filter that converts the light emitted from the respective light emitting layers (light emitting layers EM1, EM2, and EM3 shown in FIG. 5) included in the organic layers OR1, OR2, and OR3 into light of the color corresponding to subpixels SP1, SP2, and SP3. In addition, the display device DSP may comprise a layer including quantum dots that are excited by the light emitted from the light emitting layers to generate the light of the colors corresponding to those of the subpixels SP1, SP2, and SP3.

FIG. 5 is a view showing an example of a layer structure applicable to the display elements DE1, DE2, and DE3. As examples, the following description assumes cases where the lower electrodes LE1, LE2, and LE3 correspond to anodes, and the upper electrodes UE1, UE2, and UE3 correspond to cathodes. Further, the organic layers OR1, OR2, and OR3 are configured to emit colors different from each other.

The organic layer OR1 comprises a hole-injection layer HIL, a hole transport layer HTL, an electron blocking layer EBL, the light emitting layer EM1, a hole blocking layer HBL, an electron transport layer ETL, and an electron injection layer EIL. The hole-injection layer HIL is located on the lower electrode LE1. The hole transport layer HTL is located on the hole-injection layer HIL. The electron blocking layer EBL is located on the hole transport layer HTL. The light emitting layer EM1 is located on the electron blocking layer EBL. The hole blocking layer HBL is located on the light emitting layer EM1. The electron transport layer ETL is located on the hole blocking layer HBL. The electron injection layer EIL is located on the electron transport layer ETL. The upper electrode UE1 is located on the electron injection layer EIL. The light emitting layer EM1 is formed of a material emitting light in the green wavelength range. When a potential difference is formed between the lower electrode LE1 and the upper electrode UE1, the light emitting layer EM1 emits light in a green wavelength range.

If necessary, the organic layer OR1 may include other function layers such as a carrier generation layer in addition to the above function layers. Alternatively, the organic layer OR1 may exclude at least one of the above function layers.

In the display element DE2, the organic layer OR2 between the lower electrode LE2 and the upper electrode UE2 comprises the light emitting layer EM2 instead of the light emitting layer EM1. Except this point, the display element DE2 and the display element DE1 have the same configuration. In the display element DE3, the organic layer OR3 between the lower electrode LE3 and the upper electrode UE3 comprises the light emitting layer EM3 instead of the light emitting layer EM1. Except this point, the display element DE3 and the display element DE1 have the same configuration. The light emitting layer EM2 is formed of a material emitting light in a blue wavelength range. When a potential difference is formed between the lower electrode LE2 and the upper electrode UE2, the light emitting layer EM2 emits light in a blue wavelength range. The light emitting layer EM3 is formed of a material emitting light in the red wavelength range. When a potential difference is formed between the lower electrode LE3 and the upper electrode UE3, the light emitting layer EM3 emits light in a red wavelength range.

In the following description, the stacked layer body of each layer of the organic layer OR1 except the hole-injection layer HIL is referred to as a stacked film F1. The stacked layer body of each layer of the organic layer OR2 except the hole-injection layer HIL is referred to as a stacked film F2. The stacked layer body of each layer of the organic layer OR3 except the hole-injection layer HIL is referred to as a stacked film F3. That is, the stacked film F1 includes the hole transport layer HTL, the electron blocking layer EBL, the light emitting layer EM1, the hole blocking layer HBL, the electron transport layer ETL, and the electron injection layer EIL. The stacked film F2 includes the hole transport layer HTL, the electron blocking layer EBL, the light emitting layer EM2, the hole blocking layer HBL, the electron transport layer ETL, and the electron injection layer EIL. The stacked film F3 comprises the hole transport layer HTL, the electron blocking layer EBL, the light emitting layer EM3, the hole blocking layer HBL, the electron transport layer ETL, and the electron injection layer EIL.

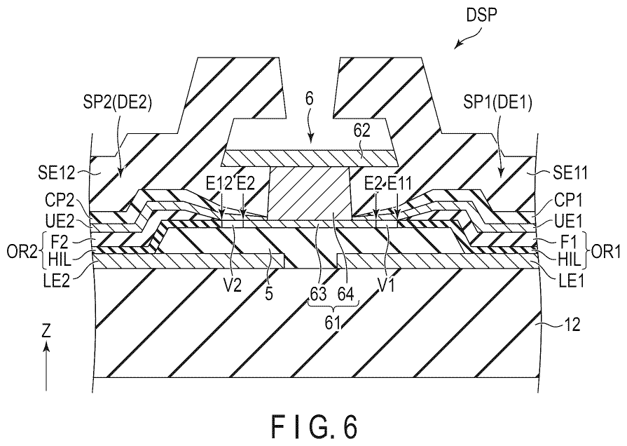

FIG. 6 is a schematic cross-sectional view showing an example of the partition 6 and its surrounding. The following will describe a configuration in the area between the subpixels SP1 and SP2. The same configuration is applicable in the area between the subpixels SP1 and SP3 and in the area between the subpixels SP2 and SP3. FIG. 6 omits the illustration of elements under the organic insulating layer 12 and the elements above the sealing layers SE11 and SE12.

The organic layer OR1 has an end portion E11 contacting the rib layer 5. The organic layer OR2 has an end portion E12 contacting the rib layer 5. The bottom layer 63 has both end portions E2 contacting the rib layer 5. In the example of FIG. 6, the end portions E11 and E2 are spaced apart from each other via a gap V1, and the end portions E12 and E2 are spaced apart from each other via a gap V2.

The gap V1 is surrounded by the rib layer 5, the bottom layer 63, the organic layer OR1, and the upper electrode UE1. In the example of FIG. 6, the gap V1 contacts the hole-injection layer HIL of the organic layer OR1. Further, the gap V1 may contact the stacked film F1.

The gap V2 is surrounded by the rib layer 5, the bottom layer 63, the organic layer OR2, and the upper electrode UE2. In the example of FIG. 6, the gap V2 contacts the hole-injection layer HIL of the organic layer OR2. Further, the gap V2 may contact the stacked film F2.

The organic layer OR1 is spaced apart from the lower portion 61 (the bottom layer 63) via the gap V1. The organic layer OR2 is spaced apart from the lower portion 61 (the bottom layer 63) via the gap V2. That is, the organic layer OR1 and the lower portion 61 are electrically insulated from each other via the gap V1. Similarly, the organic layer OR2 and the lower portion 61 are electrically insulated from each other via the gap V2. The gaps V1 and V2 need not necessarily be formed. That is, the end portions E11 and E2 may contact each other, and the end portions E12 and E2 may contact each other. In this case as well, the organic layers OR1 and OR2 and the lower portion 61 are electrically insulated from each other.

In the manufacturing of the display device DSP, a large mother substrate is fabricated, the mother substrate comprising a plurality of areas (panel portions) each corresponding to the display panel PNL. The following will describe a configuration applicable to this mother substrate.

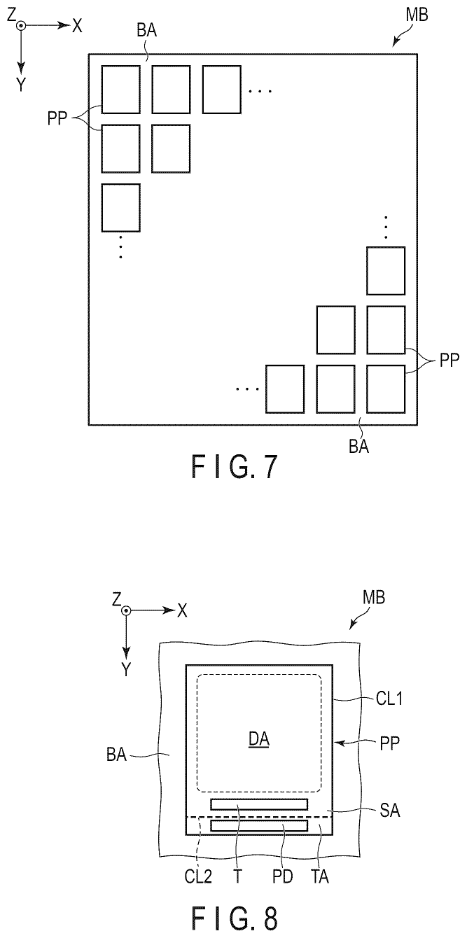

FIG. 7 is a schematic plan view of a mother substrate MB (a mother substrate for a display device) according to an embodiment. For example, the mother substrate MB has a rectangular shape as shown in the figure. However, the mother substrate MB may have another shape such as a circular shape.

The mother substrate MB comprises a plurality of panel portions PP provided in a matrix and a margin area BA around these panel portions PP. In the example of FIG. 7, the panel portions PP are arranged in the X direction and the Y direction via the margin area BA. However, at least two of the panel portions PP provided in the mother substrate MB may be adjacent to each other without intervention of the margin area BA.

FIG. 8 is a schematic plan view of a part of the mother substrate MB. This figure focuses attention on one panel portion PP. The outer shape of the panel portion PP corresponds to a cut line CL1 for cutting out the panel portion PP from the mother substrate MB.

Each panel portion PP has the display area DA and the surrounding area SA. Further, the surrounding area SA includes an inspection area TA. In the inspection area TA, an inspection pad PD for inspecting the operation of the display panel PNL and the like are provided.

In each panel portion PP, a cut line CL2 is formed. This cut line CL2 divides the panel portions PP into a part including the display area DA and a part including the inspection area TA.

In the manufacturing of the display device DSP, the panel portion PP is first cut out from the mother substrate MB along the cut line CL1. Further, this cut-out panel portion PP is subjected to the inspection using the inspection pad PD. After this inspection, the inspection area TA is cut out from the panel portion PP along the cut line CL2.

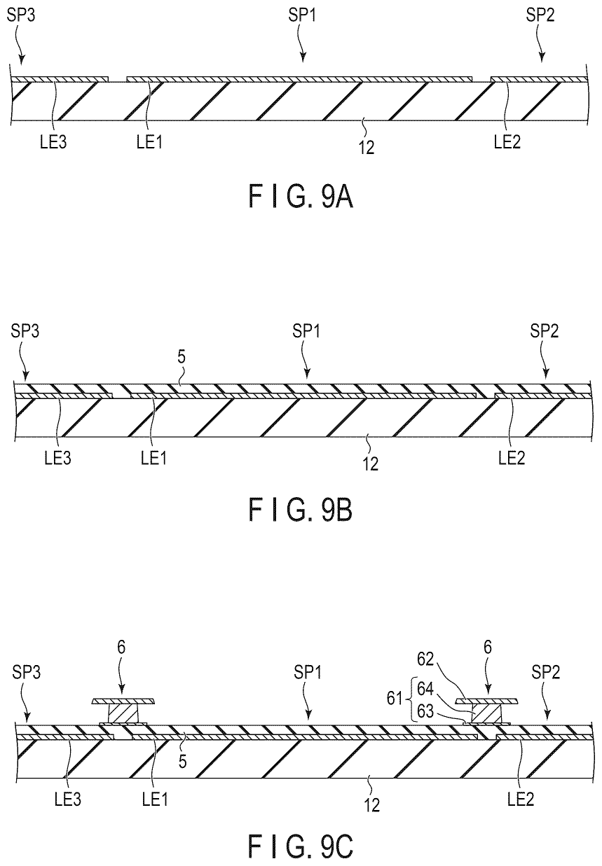

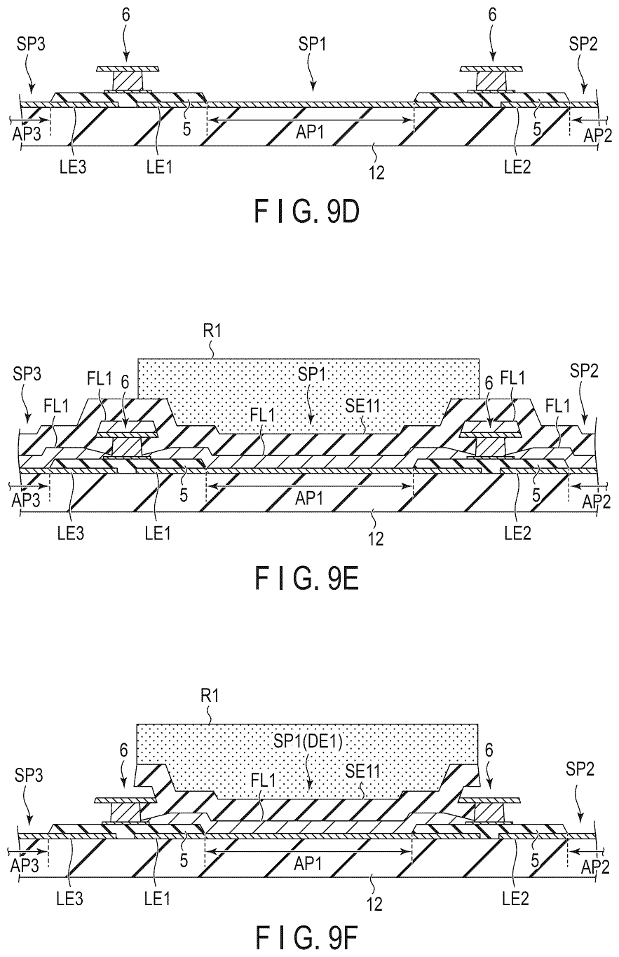

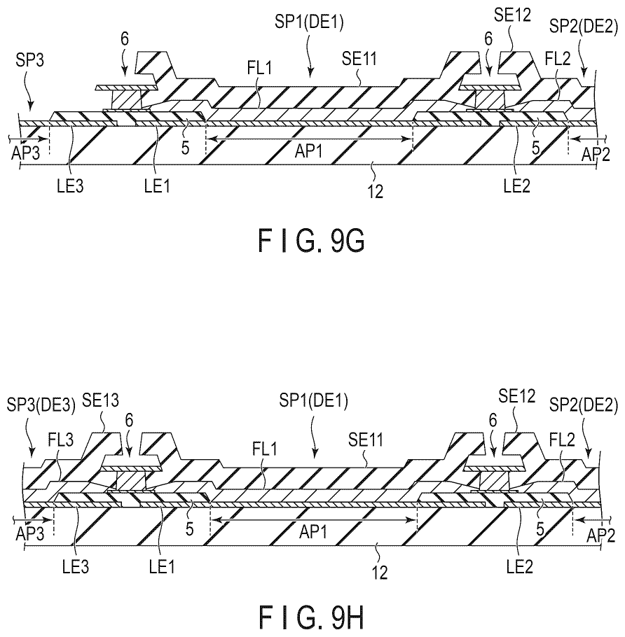

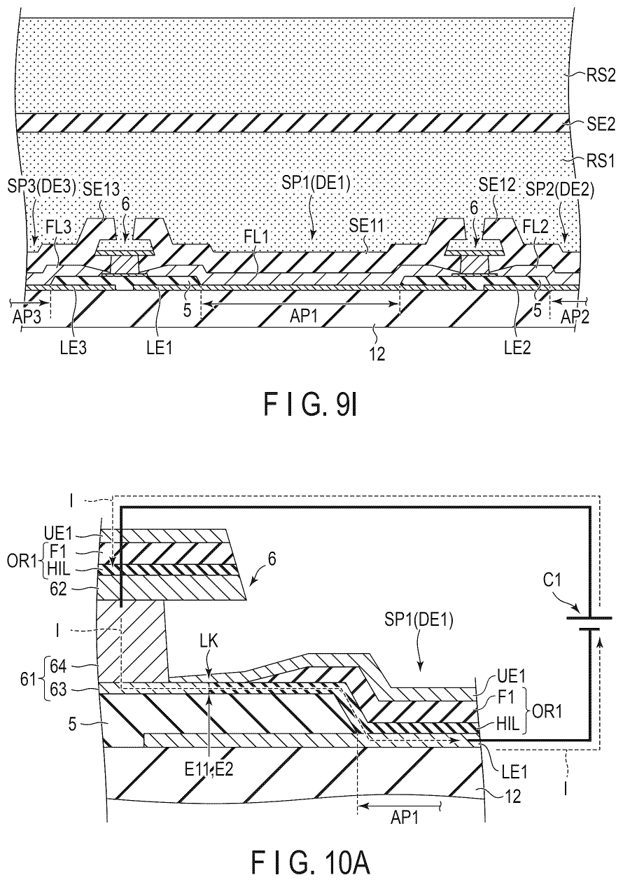

The following will describe an example of the manufacturing method of the display device DSP. FIG. 9A to FIG. 9I are schematic cross-sectional views showing the manufacturing processes of the display device DSP. FIG. 9A to FIG. 9I mainly focus on the display area DA and omit the illustration of elements under the organic insulating layer 12.

In the manufacturing of the display device DSP, first, the circuit layer 11 and the organic insulating layer 12 are formed on the substrate 10. Next, as shown in FIG. 9A, the lower electrodes LE1, LE2, and LE3 are formed on the organic insulating layer 12.

Subsequently, as shown in FIG. 9B, the rib layer 5 covering the lower electrodes LE1, LE2, and LE3 is formed. An inorganic material may be used for the rib layer 5. At this time, the pixel apertures AP1, AP2, and AP3 are not provided in the rib layer 5. The rib layer 5 can be formed by chemical vapor deposition (CVD).

After the formation of the rib layer 5, a process for forming the partition 6 is performed. In this process, a layer to be processed into the bottom layer 63, a layer to be processed into the stem layer 64, and a layer to be processed into the top layer 62 are sequentially formed. Thereafter, a resist patterned in a shape of the partition 6 is provided. Each of the above layers is patterned using this resist as a mask. Thus, as shown in FIG. 9C, the partition 6 is formed.

Next, the process for providing the pixel apertures AP1, AP2, and AP3 is performed. In this process, a resist covering the partition 6 is formed. The rib layer 5 is patterned using this resist as a mask. Thus, as shown in FIG. 9D, the pixel apertures AP1, AP2, and AP3 are formed in the rib layer 5. The respective lower electrodes LE1, LE2, and LE3 are exposed from the pixel apertures AP1, AP2, and AP3. The process of forming the partition 6 may be performed after the process of forming the pixel apertures AP1, AP2, and AP3 in the rib layer 5.

Next, the process for forming the display element DE1 is performed. As shown in FIG. 9E, in the formation of the display element DE1, the stacked film FL1 and the sealing layer SE11 are formed first. As shown in FIG. 4, the stacked film FL1 includes the organic layer OR1 contacting the lower electrode LE1 through the pixel aperture AP1, the upper electrode UE1 covering the organic layer OR1, and the cap layer CP1 covering the upper electrode UE1. The partition 6 having an overhang shape divides the stacked film FL1 into a plurality of parts. The sealing layer SE11 continuously covers these parts, into which the stacked film FL1 has been divided, and the partition 6.

For example, the organic layer OR1, the upper electrode UE1, and the cap layer CP1 may be formed by vapor deposition. For example, the sealing layer SE11 may be formed by CVD.

Subsequently, the stacked film FL1 and the sealing layer SE11 are patterned. As shown in FIG. 9E, the resist R1 is provided on the sealing layer SE11 in this patterning. The resist R1 covers the subpixel SP1 and a part of the partition 6 around the subpixel SP1.

Thereafter, the etching process using the resist R1 as a mask is performed. As shown in FIG. 9F, parts exposed from the resist R1 of the stacked film FL1 and the sealing layer SE11 are removed. That is, parts overlapping the lower electrode LE1 of the stacked film FL1 and the sealing layer SE11 remain. The other parts are removed. Thus, the display element DE1 is formed in the subpixel SP1. This etching process may include wet etching and dry etching performed in order for the sealing layer SE11, the cap layer CP1, the upper electrode UE1, and the organic layer OR1. After these etching processes, the resist R1 is removed (stripped).

The stacked film FL1 located under the sealing layer SE11 on the partition 6 is also removed in wet etching for the stacked film FL1. This process forms a gap between the sealing layer SE11 located above the partition 6 and the partition 6. The stacked film FL1 constituting the display element DE1 is completely surrounded by the sealing layer SE11 and the partition 6. Thus, this stacked film FL1 is not corroded by the wet etching.

Next, the process for forming the display element DE2 is performed. The display element DE2 can be formed by the same procedure as that of the display element DE1. That is, in the formation of the display element DE2, the stacked film FL2 and the sealing layer SE12 are formed. As shown in FIG. 4, the stacked film FL2 includes the organic layer OR2 contacting the lower electrode LE2 through the pixel aperture AP2, the upper electrode UE2 covering the organic layer OR2, and the cap layer CP2 covering the upper electrode UE2.

The organic layer OR2, the upper electrode UE2, and the cap layer CP2 may be formed by, for example, vapor deposition. The sealing layer SE12 may be formed by, for example, CVD. The partition 6 having an overhang shape divides the stacked film FL2 into a plurality of parts. The sealing layer SE12 continuously covers these parts, into which the stacked film FL2 has been divided, and the partition 6. As shown in FIG. 9G, patterning these stacked film FL2 and sealing layer SE2 forms the display element DE2 in the subpixel SP2.

Next, the process for forming the display element DE3 is performed. The display element DE3 can be formed by the same procedures as those of the display elements DE1 and DE2. That is, in the formation of the display element DE3, the stacked film FL3 and the sealing layer SE13 are formed. As shown in FIG. 4, the stacked film FL3 includes the organic layer OR3 contacting the lower electrode LE3 through the pixel aperture AP3, the upper electrode UE3 covering the organic layer OR3, and the cap layer CP3 covering the upper electrode UE3.

The organic layer OR3, the upper electrode UE3, and the cap layer CP3 may be formed by, for example, vapor deposition. The sealing layer SE13 may be formed by, for example, CVD. The partition 6 having an overhang shape divides the stacked film FL3 into a plurality of parts. The sealing layer SE13 continuously covers these parts, into which the stacked film FL3 has been divided, and the partition 6. As shown in FIG. 9H, patterning these stacked film FL3 and sealing layer SE13 forms the display element DE3 in the subpixel SP3.

Here, the above description assumes that the display elements DE1, DE2, and DE3 are formed in this order. However, the display elements DE1, DE2, and DE3 may be formed in another order.

As shown in FIG. 9I, after the formations of the display elements DE1, DE2, and DE3, the resin layer RS1, the sealing layer SE2, and the resin layer RS2 are sequentially formed. Further, each panel portion PP is cut out from the mother substrate MB along the cut line CL1.

Thereafter, each panel portion PP undergoes inspection. This inspection includes illumination inspection of the display elements DE1, DE2, and DE3 using the inspection pad PD provided in the inspection area TA and the like. After this inspection, the inspection area TA is cut out along the cut line CL2. This completes the display panel PNL.

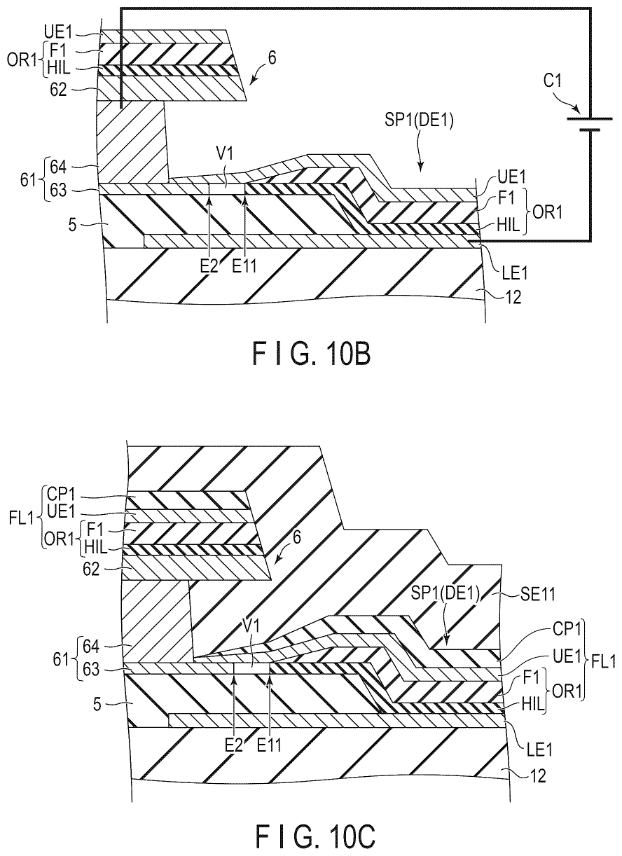

FIG. 10A to FIG. 10C are schematic cross-sectional views showing an example of a process for electrically insulating the organic layer OR1 and the partition 6 from each other. For example, this process is performed between the process shown in FIG. 9D and the process shown in FIG. 9E.

After the formation of the pixel apertures AP1, AP2, and AP3, the organic layer OR1 covering the lower electrode LE1 through the pixel aperture AP1 and the upper electrode UE1 covering the organic layer OR1 are formed as shown in FIG. 10A. The organic layer OR1 has the hole-injection layer HIL and the stacked film F1. The hole-injection layer HIL contacts the lower electrode LE1. In the example of FIG. 10A, the hole-injection layer HIL is formed on the lower electrode LE1 and the rib layer 5, the stacked film F1 is formed on the hole-injection layer HIL, and the upper electrode UE1 is formed on the stacked film F1. The hole-injection layer HIL, the stacked film F1, and the upper electrode UE1 are stacked on the upper portion 62.

At this time, unintended manufacturing process variations and the like may potentially cause the organic layer OR1 and the lower portion 61 to partially contact each other in the mother substrate MB. That is, the extremely thin organic layer OR1 may potentially contact the end portion E2 of the bottom layer 63. FIG. 10A shows a case where the end portion E11 of the hole-injection layer HIL contacts the end portion E2 of the bottom layer 63. That is, FIG. 10A shows a state where the extremely thin hole-injection layer HIL contacts the end portion E2 of the bottom layer 63. Here, the state where the end portions E11 and E2 contacts each other signifies that electrical conduction is achieved between the end portions E11 and E2. In this case, the contact area of the end portions E11 and E2 constitutes a leakage portion LK. For example, the electrical resistance of the leakage portion LK per pixel due to the contact between the end portions E11 and E2 is not less than several tens of GΩ and not more than several hundreds of GΩ.

As shown in FIG. 10A, after the formation of the upper electrode UE1, the partition 6 and the lower electrode LE1 are connected to a power source C1. In the example shown in FIG. 10A, the power source C1 is a direct current (DC) power source. Further, the partition 6 is connected to the high potential side, and the lower electrode LE1 is connected to the low potential side.

Next, a voltage is applied between the partition 6 and the lower electrode LE1 to apply a current I from the partition 6 on the high potential side to the lower electrode LE1 on the low potential side. In the example of FIG. 10A, the end portion E11 of the hole-injection layer HIL and the end portion E2 of the bottom layer 63 contact each other at the leakage portion LK. Thus, the current I sequentially flows through the bottom layer 63, the hole-injection layer HIL, and the lower electrode LE1. When the lower electrode LE1 corresponds to the anode and the upper electrode UE1 corresponds to the cathode, applying the current I to from the partition 6 toward the lower electrode LE1 (applying a reverse bias voltage) causes almost no current to flow between the lower electrode LE1 and the upper electrode UE1. Thus, the current I flows mainly through the leakage portion LK.

The current I flowing through the leakage portion LK removes a part in the vicinity of the leakage portion LK of the organic layer OR1. Thus, as shown in FIG. 10B, the end portion E11 recedes. This configuration causes the end portions E11 and E2 to be spaced apart from each other, forming the gap V1 between the lower portion 61 and the organic layer OR1. That is, the lower portion 61 and the organic layer OR1 are electrically insulated from each other. In the example shown in FIG. 10B, the gap V1 is formed between the bottom layer 63 and the hole-injection layer HIL. Thus, the bottom layer 63 and the hole-injection layer HIL are electrically insulated from each other. The gap V1 need not necessarily be formed. That is, the end portions E11 and E2 may contact each other. Even in this case, the current I flowing through the leakage portion LK electrically insulates the partition 6 and the organic layer OR1 from each other.

For example, the magnitude of the voltage applied in the above process (the potential difference between the partition 6 and the lower electrode LE1) is 20 V or less. In one example, the magnitude of the voltage is 10 to 20 V. Furthermore, in one example, the time for applying the voltage (the time of the current I flowing) is 2 seconds or less. The voltage magnitude and time are not limited to this example.

Subsequently, as shown in FIG. 10C, the cap layer CP1 covering the upper electrode UE1 and the sealing layer SE11 covering the cap layer CP1 are formed. Then, as shown in FIG. 9E and FIG. 9F, an etching process to form the display element DE1 is performed.

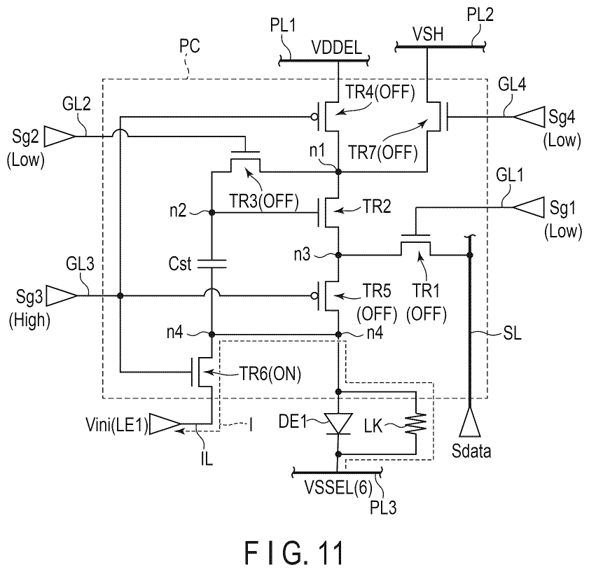

FIG. 11 is a circuit diagram in the process shown in FIG. 10A. The leakage portion LK is connected in parallel with the display element DE1.

In this process, the L-level scanning signals Sg1, Sg2, and Sg4 and the H-level scanning signal Sg3 are supplied to each transistor. Thus, as shown in FIG. 11, the transistor TR6 enters the ON state, and the transistors TR1, TR3 to TR5, and TR7 enter the OFF state.

The partition 6 shown in FIG. 10A is connected to the power line PL3 and is supplied with the power source voltage VSSEL. Furthermore, the lower electrode LE1 is connected to the initialization line IL and is supplied with the initialization voltage Vini. For example, the power source voltage VSSEL and the initialization voltage Vini are supplied from the test pad PD shown in FIG. 8. In the present embodiment, the power supply voltage VSSEL is higher than the initialization voltage VinI (VSSEL>VinI). Consequently, the current I flows from the partition 6 toward the lower electrode LE1. As shown in FIG. 11, the current I flows through the leakage portion LK while scarcely flowing through the display element DE1. After flowing through the leakage portion LK, the current I flows into the transistor TR6.

Here, if the display device DSP is manufactured with the organic layer OR1 and the partition 6 in contact and conductive, current may potentially leak between the organic layer OR1 and the partition 6 via the leakage portion LK. As a result, insufficient current may potentially flow through the organic layer OR1 due to the leakage, potentially preventing the display element DE1 from emitting light in the intended color. This situation can be particularly problematic when attempting to express colors in the low-gradation range, such as when the display element DE1 is demanded to emit light in a gray close to black.

Thus, the organic layer OR1 has to be formed so as not to contact the lower portion 61. However, in the manufacturing process, unintended contact between the organic layer OR1 and the lower portion 61 may potentially occur.

In the present embodiment, applying a voltage between the partition 6 and the lower electrode LE1 causes the current I to flow through the leakage portion LK, electrically insulating the lower portion 61 and the organic layer OR1 from each other. This suppresses the current leakage between the lower portion 61 and the organic layer OR1, preventing emitting light in unintended color. Thus, deterioration in the brightness characteristics (display quality) of the display device DSP can be suppressed.

The above problem is particularly likely to occur when the hole-injection layer HIL of the organic layer OR1 contacts the lower portion 61. When the hole-injection layer HIL contacts the lower portion 61, holes flow from the hole-injection layer HIL to the lower portion, reducing the supply of holes to the light emitting layer EM1. This prevents the light emitting layer EM1 from emitting light in the intended color. Therefore, as shown in the present embodiment, electrically insulating the lower portion 61 and the hole-injection layer HIL from each other prevents emitting light in unintended color and suppresses the deterioration of the brightness characteristics of the display device DSP.

The above process of applying current can also be performed when the lower portion 61 and the organic layer OR1 are spaced apart from each other. When the lower portion 61 and the organic layer OR1 are spaced apart from each other, no current flows between the partition 6 and the lower electrode LE1. Thus, no problems arise in the above process. Thus, the process of applying the current can be performed without inspecting whether the lower portion 61 and the organic layer OR1 are spaced apart from each other. This results in a reduction in the manufacturing processes of the display device DSP.

Further, in the present embodiment, the potential of the partition 6 is higher than that of the lower electrode LE1. Thus, the current I flows from the partition 6 toward the lower electrode LE1. When the lower electrode LE1 corresponds to the anode, the upper electrode UE1 corresponds to the cathode, and the current I flows from the partition 6 toward the lower electrode LE1 (applying a reverse bias voltage), almost no current flows between the lower electrode LE1 and the upper electrode UE1. Thus, damage to the organic layer OR1 due to a current flowing between the lower electrode LE1 and the upper electrode UE1 can be prevented. Thus, deterioration in the display quality of the display device DSP can be suppressed.

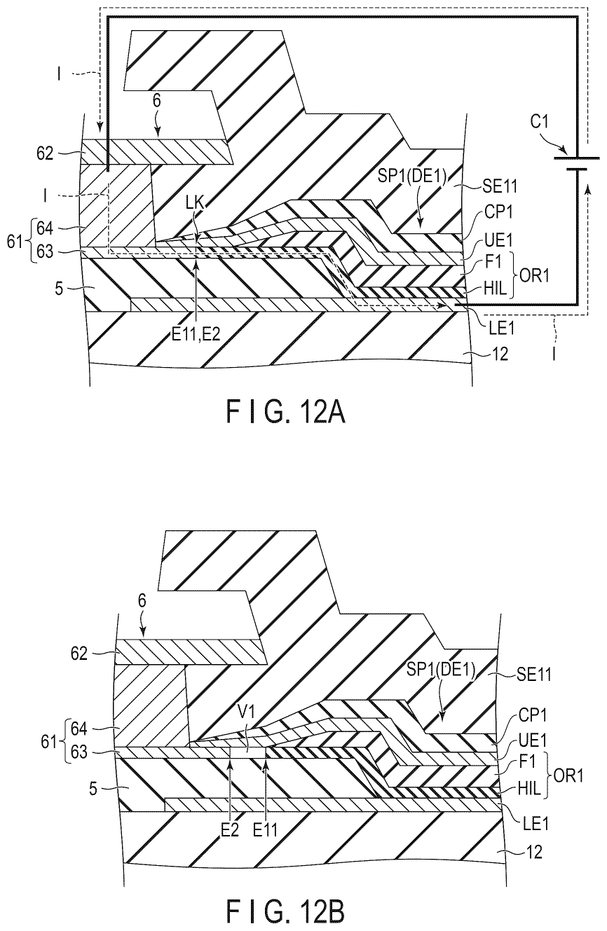

FIG. 12A to FIG. 12B are schematic cross-sectional views showing another example of the process for electrically insulating the organic layer OR1 and the partition 6 from each other. In the example shown in FIG. 12A, the process of applying the current I is performed after the formation of the cap layer CP1 and the sealing layer SE11. In the process of applying the current I, the current I flows from the partition 6, connected to a high potential side, to the lower electrode LE1, connected to a low potential side, via the leakage portion LK. Thus, as shown in FIG. 12B, the gap V1 is formed. Consequently, the lower portion 61 and the organic layer OR1 are electrically insulated from each other.

For example, the processes shown in FIG. 12A and FIG. 12B are performed between the process shown in FIG. 9H and the process shown in FIG. 9I. That is, the process of applying the current I is performed after the formation of the cap layers CP1, CP2, and CP3 and the sealing layers SE11, SE12, and SE13. In this case, the current I is applied only once. Thus, the number of the processes can be reduced compared to applying the current I each time in the formation of the respective display elements DE1, DE2, and DE3.

The processes shown in FIG. 12A and FIG. 12B may also be performed each time in the formation of the respective display elements DE1, DE2, and DE3. That is, the processes shown in FIG. 12A and FIG. 12B may be performed between FIG. 9F and FIG. 9G, between FIG. 9G and FIG. 9H, and between FIG. 9H and FIG. 9I. The same effects as those described above can be achieved in this case as well.

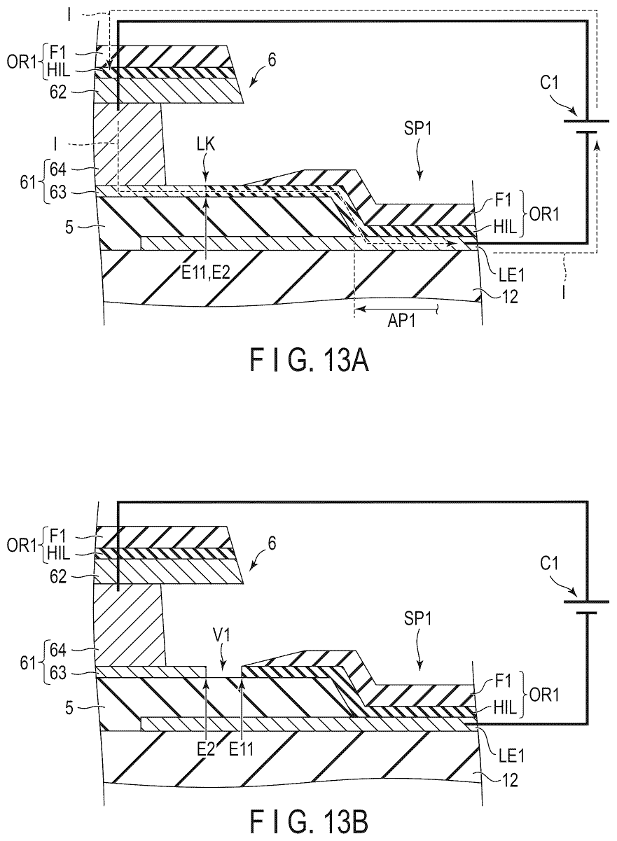

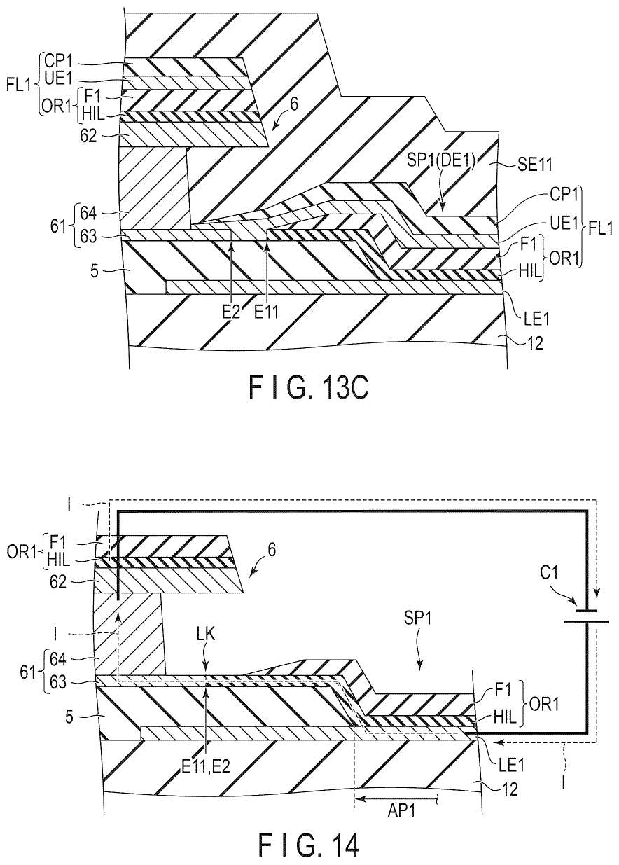

FIG. 13A to FIG. 13C are schematic cross-sectional views showing still another example of the process for electrically insulating the organic layer OR1 and the partition 6 from each other. This process is performed between the process shown in FIG. 9D and the process shown in FIG. 9E.

After the formation of the pixel apertures AP1, AP2, and AP3, the organic layer OR1 covering the lower electrode LE1 through the pixel aperture AP1 is formed as shown in FIG. 13A. Next, the partition 6 and the lower electrode LE1 are connected to the power source C1. In the example shown in FIG. 13A, the partition 6 is connected to the high potential side, and the lower electrode LE1 is connected to the low potential side. Thereafter, as described above, the current I flows from the partition 6 toward the lower electrode LE1. Thus, as shown in FIG. 13B, the gap V1 is formed. Consequently, the lower portion 61 and the organic layer OR1 are electrically insulated from each other.

After the process of applying the current I, the upper electrode UE1 covering the organic layer, the cap layer CP1 covering the upper electrode UE1, and the sealing layer SE11 covering the cap layer CP1 are formed. The upper electrode UE1 contacts the rib layer 5 between the end portions E11 and E2.

In this manner, the process of applying the current I to the leakage portion LK can be performed as described above even after the formation of the organic layer OR1 and before the formation of the upper electrode UE1. In this case, the upper electrode UE1 has not yet been formed, and thus the organic layer OR1 will not be damaged by the current flowing between the lower electrode LE1 and the upper electrode UE1. Thus, deterioration in the display quality of the display device DSP can be suppressed.

Further, when the current I is applied before the formation of the upper electrode UE1, the flowing direction of the current I is not limited to the direction from the partition 6 toward the lower electrode LE1. Thus, the lower electrode LE1 may be connected to the high potential side and the partition 6 may be connected to the low potential side, and thus the current I may flow from the lower electrode LE1 to the partition 6. Further, an alternating voltage may also be applied.

FIG. 14 is a schematic cross-sectional view showing another example of the process shown in FIG. 13A. In the example shown in FIG. 14, the partition 6 is connected to the low potential side, and the lower electrode LE1 is connected to the high potential side. Thus, the current I flows from the lower electrode LE1 toward the partition 6.

Thus, the current I may flow from the lower electrode LE1 toward the partition 6 before the formation of the upper electrode UE1. Performing this process can achieve the same effects as those described above.

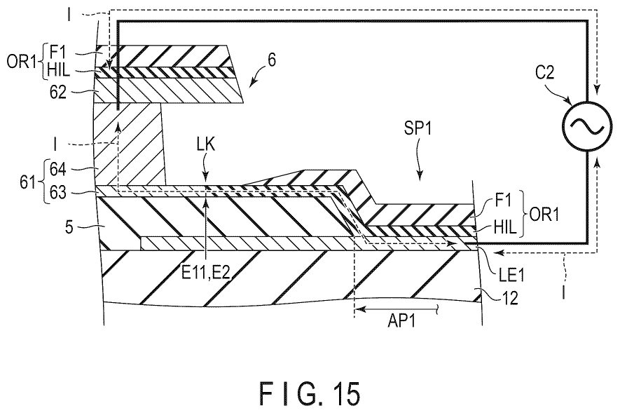

FIG. 15 is a schematic cross-sectional view showing still another example of the process shown in FIG. 13A. In the example shown in FIG. 15, the partition 6 and the lower electrode LE1 are connected to an alternating-current power source C2. Therefore, an AC bias voltage is applied between the partition 6 and the lower electrode LE1. Thus, the current I that is an alternating current flows between the partition 6 and the lower electrode LE1.

Thus, an AC bias voltage may be applied such that the current I may flow between the partition 6 and the lower electrode LE1 before the formation of the upper electrode UE1. Performing this process can achieve the same effects as those described above.

All of the manufacturing methods of the display devices that can be implemented by a person of ordinary skill in the art through arbitrary design changes to the manufacturing method of the display device described above as the embodiments of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is

1. A manufacturing method of a display device, the method comprising steps of:
forming a lower electrode in a display area for displaying images;
forming a rib layer of an inorganic material covering the lower electrode;
forming a partition having a lower portion provided on the rib layer and having conductivity and an upper portion provided on the lower portion and protruding relative to a side surface of the lower portion;
forming a pixel aperture overlapping the lower electrode in the rib layer;
forming an organic layer covering the lower electrode through the pixel aperture; and
applying a current between the partition and the lower electrode to electrically insulate the lower portion and the organic layer from each other.

2. The manufacturing method of claim 1, wherein
the organic layer includes a hole-injection layer contacting the lower electrode, and
the lower portion and the hole-injection layer are electrically insulated from each other in the step of applying the current.

3. The manufacturing method of claim 1, further comprising steps of:
forming an upper electrode covering the organic layer and contacting the lower portion between the step of forming the organic layer and the step of applying the current; and
forming a cap layer covering the upper electrode and a sealing layer covering the cap layer after the step of applying the current.

4. The manufacturing method of claim 1, further comprising a step of:
between the step of forming the organic layer and the step of applying the current, forming an upper electrode covering the organic layer and contacting the lower portion, a cap layer covering the upper electrode, and a sealing layer covering the cap layer.

5. The manufacturing method of claim 1, further comprising a step of:
after the step of applying the current, forming an upper electrode covering the organic layer and contacting the lower portion, a cap layer covering the upper electrode, and a sealing layer covering the cap layer.

6. The manufacturing method of claim 3, wherein
the lower electrode corresponds to an anode,
the upper electrode corresponds to a cathode, and
the current is applied from the partition toward the lower electrode in the step of applying the current.

7. The manufacturing method of claim 4, wherein
the lower electrode corresponds to an anode,
the upper electrode corresponds to a cathode, and
the current is applied from the partition toward the lower electrode in the step of applying the current.

8. The manufacturing method of claim 5, wherein
the lower electrode corresponds to an anode,
the upper electrode corresponds to a cathode, and
the current is applied from the partition toward the lower electrode in the step of applying the current.

9. The manufacturing method of claim 5, wherein
the lower electrode corresponds to an anode,
the upper electrode corresponds to a cathode, and
the current is applied from the lower electrode toward the partition in the step of applying the current.

10. The manufacturing method of claim 5, wherein
an AC bias voltage is applied in the step of applying the current.

11. The manufacturing method of claim 1, wherein
the potential difference between the partition and the lower electrode is 20 V or less in the step of applying the current.

12. The manufacturing method of claim 1, wherein
a time for applying the current is 2 seconds or less.

13. The manufacturing method of claim 1, wherein
the lower portion includes a bottom layer provided on the rib layer and a stem layer provided on the bottom layer, and
the bottom layer and the organic layer are electrically insulated from each other in the step of applying the current.

14. The manufacturing method of claim 13, wherein
the organic layer includes a hole-injection layer contacting the bottom layer, and
the bottom layer and the hole-injection layer are electrically insulated from each other in the step of applying the current.
